(19) United States
(12) Patent Application Publication
(10) Pub. No.: US 2013/0107180 A1
(43) Pub. Date: May 2, 2013

(54) LIQUID CRYSTAL DISPLAY DEVICE AND METHOD FOR FABRICATING THE SAME

(71) Applicants: Dan Xiao, Guangdong (CN); Chun He, Guangdong (CN)

(72) Inventors: Dan Xiao, Guangdong (CN); Chun He, Guangdong (CN)

(73) Assignee: SHENZHEN CHINA STAR OPTOELECTRONICS TECHNOLOGY CO., LTD., Shenzhen (CN)

(21) Appl. No.: 13/379,570

(22) PCT Filed: Nov. 4, 2011
(86) PCT No.: PCT/CN11/81829

§ 371 Date: Dec. 20, 2011

(30) Foreign Application Priority Data
Nov. 2, 2011 (CN) 201110341164.7

(51) Int. Cl. G02F 1/1333; G03F 7/20

(52) U.S. Cl. 349/110; 430/320

(57) ABSTRACT

The present invention relates a liquid crystal display device and a method for fabricating the same. The liquid crystal display device includes two glass substrates and a liquid crystal layer which is disposed between the two glass substrates, a plurality of pixel regions formed on the glass substrates. A photoresist layer and a transparent electrode layer are sequentially disposed on a side of the at least one glass substrate adjacent to the liquid crystal layer, the photoresist layer forms at least one concave and/or at least one protrusion in each of the pixel regions. The liquid crystal display device and the method for fabricating the same are simpler.

### FIELD OF THE INVENTION

The present invention relates to a liquid crystal display (LCD) technology, and especially to a liquid crystal display device and a method for fabricating the same.

### BACKGROUND OF THE INVENTION

With a rapid growth and development in liquid crystal display technology, high-quality display devices require higher resolution and a wider viewing angle display effect. For vertical alignment types of liquid-crystal displays, pixel regions of the liquid-crystal display generally perform an alignment partition, so that liquid-crystal molecules in different pixel regions tilt toward various directions. Thus, after voltages are applied, light beams can be seen from a plurality of angles, thereby increasing the display effect of the wide viewing angle of the liquid crystal displays.

The conventional way of forming the alignment partition in the liquid crystal display includes two methods as follows.

1, forming protrusions on a passive layer, thereby the liquid-crystal molecules in different pixel regions tilt toward various directions, and the liquid-crystal molecules are twisted in various directions when applying a voltage for improving the viewing angle of the liquid-crystal display. However, it is difficult to fabricate the protrusions on the passive layer, as well as difficult to control while fabricating the protrusions.

2, using an etching technology, slits or openings are dug in a transparent electrode layer, thereby achieving the effect of the above-mentioned technology. However, the fabricating processes of digging the slits or making the openings in the transparent electrode layer are relatively complex by employing this technology.

Therefore, there is a significant need to provide a liquid crystal display device and a method for fabricating the same to solve the problems currently existing in the prior art.

### SUMMARY OF THE INVENTION

An objective of the present invention is to provide a liquid crystal display device and a method for fabricating the same to solve the problems of difficulties in fabricating the liquid crystal display device in the prior art.

The present invention relates to a liquid crystal display device, which includes two glass substrates and a liquid crystal layer disposed between the two glass substrates, and a plurality of pixel regions is formed on the glass substrates. A photoresist layer and a transparent electrode layer are sequentially disposed on a side of the at least one glass substrate adjacent to the liquid crystal layer, the photoresist layer forms at least one concave and/or at least one protrusion in each of the pixel regions. A sectional width of the concave and/or the protrusion is 0.5 to 20 micrometers. A sectional depth of the concave and/or the protrusion is 100 to 1000 angstroms.

In the liquid crystal display device of the present invention, the photoresist layer forms the at least one concave and the plurality of protrusions around the concave in each of the pixel regions, or the photoresist layer forms the at least one protrusion and the plurality of concaves around the protrusion in each of the pixel regions.

In the liquid crystal display device of the present invention, the two glass substrates respectively are a first glass substrate and a second glass substrate, the plurality of pixel regions formed on the first glass substrate and the second glass substrate, the photoresist layers formed on both the first glass substrate and the second glass substrate. A shape of photoresist layer on the first glass substrate is different from a shape of photoresist layer on the second glass substrate.

In the liquid crystal display device of the present invention, the photoresist layer on the first glass substrate forms the at least one concave in each of the pixel regions, and the photoresist layer on the second glass substrate forms the at least one protrusion in each of the pixel regions.

In the liquid crystal display device of the present invention, the photoresist layer on the first glass substrate forms the at least one protrusion in each of the pixel regions, and the photoresist layer on the second glass substrate forms the at least one concave in each of the pixel regions.

In the liquid crystal display device of the present invention, the photoresist layer on the first glass substrate forms the at least one concave and the plurality of protrusions around the concave in each of the pixel regions, and the photoresist layer on the second glass substrate forms the at least one protrusion and the plurality of concaves around the protrusion in each of the pixel regions.

In the liquid crystal display device of the present invention, the photoresist layer on the first glass substrate forms the at least one protrusion and the plurality of concaves around the protrusion in each of the pixel regions, and the photoresist layer on the second glass substrate forms the at least one concave and the plurality of protrusions around the concave in each of the pixel regions.

The present invention further relates a liquid crystal display device, which includes two glass substrates and a liquid crystal layer disposed between the two glass substrates, and a plurality of pixel regions is formed on the glass substrates. A photoresist layer and a transparent electrode layer are sequentially disposed on a side of the at least one glass substrate adjacent to the liquid crystal layer, the photoresist layer forms at least one concave and/or at least one protrusion in each of the pixel regions.

In the liquid crystal display device of the present invention, the photoresist layer forms the at least one concave and the plurality of protrusions around the concave in each of the pixel regions.

In the liquid crystal display device of the present invention, the photoresist layer forms the at least one protrusion and the plurality of concaves around the protrusion in each of the pixel regions.

In the liquid crystal display device of the present invention, a sectional width of the concave and/or the protrusion is 0.5 to 20 micrometers.

In the liquid crystal display device of the present invention, a sectional depth of the concave and/or the protrusion is 100 to 1000 angstroms.

In the liquid crystal display device of the present invention, a sectional shape of the concave and/or the protrusion is a circle, a trapezoid, or a polygon.

In the liquid crystal display device of the present invention, the two glass substrates are respectively a first glass substrate and a second glass substrate, the plurality of pixel regions formed on the first glass substrate and the second glass substrate, the photoresist layers formed on both the first glass substrate and the second glass substrate.

In the liquid crystal display device of the present invention, a shape of photoresist layer on the first glass substrate is different from a shape of photoresist layer on the second glass substrate.

In the liquid crystal display device of the present invention, the photoresist layer on the first glass substrate forms the at least one concave in each of the pixel regions, and the photoresist layer on the second glass substrate forms the at least one protrusion in each of the pixel regions.

In the liquid crystal display device of the present invention, the photoresist layer on the first glass substrate forms the at least one protrusion in each of the pixel regions, and the photoresist layer on the second glass substrate forms the at least one concave in each of the pixel regions.

In the liquid crystal display device of the present invention, the photoresist layer on the first glass substrate forms the at least one concave and the plurality of protrusions around the concave in each of the pixel regions, and the photoresist layer on the second glass substrate forms the at least one protrusion and the plurality of concaves around the protrusion in each of the pixel regions.

In the liquid crystal display device of the present invention, the photoresist layer on the first glass substrate forms the at least one protrusion and the plurality of concaves around the protrusion in each of the pixel regions, and the photoresist layer on the second glass substrate forms the at least one concave and the plurality of protrusions around the concave in each of the pixel regions.

The present invention further relates a method for fabricating a liquid crystal display device, comprising the steps of: (A) sequentially depositing a passive layer and a photoresist layer on a glass substrate; (B) patterning the photoresist layer through a photo mask to form at least one concave and/or at least one protrusion on the photoresist layer; (C) depositing a transparent electrode layer on the photoresist layer.

The liquid crystal display device and the method for fabricating the same of the present invention realize the alignment partition of the liquid crystal display device by means of fabricating the protrusions and the concaves in the photoresist layer, thus the problems of complicatedly fabricating the alignment partition of the liquid crystal display device in the prior art are solved.

It is to be understood that both the foregoing general description and the following detailed description of the present invention are exemplary and explanatory and are intended to provide further explanation of the invention as claimed.

### DESCRIPTION OF THE DRAWINGS

FIG. 1 is a schematic drawing illustrating a liquid crystal display device according to a first preferred embodiment of the present invention.

FIG. 2 is a schematic drawing illustrating a liquid crystal display device according to a second preferred embodiment of the present invention.

FIG. 3 is a schematic drawing illustrating a liquid crystal display device according to a third preferred embodiment of the present invention.

FIG. 4 is a first schematic drawing illustrating concave and/or protrusion of a photoresist layer of the liquid crystal display device of the present invention;

FIG. 5 is a second schematic drawing illustrating the concave and/or the protrusion of the photoresist layer of the liquid crystal display device of the present invention;

FIG. 6 is a third schematic drawing illustrating the concave and/or the protrusion of the photoresist layer of the liquid crystal display device of the present invention;

FIG. 7 is a fourth schematic drawing illustrating the concave and/or the protrusion of the photoresist layer of the liquid crystal display device of the present invention;

FIG. 8 is a fifth schematic drawing illustrating the concave and/or the protrusion of the photoresist layer of the liquid crystal display device of the present invention; and

FIG. 9 is a sixth schematic drawing illustrating the concave and/or the protrusion of the photoresist layer of the liquid crystal display device of the present invention.

### DETAILED DESCRIPTION OF THE PREFERRED EMBODIMENTS

Descriptions of the following embodiments refer to attached drawings which are utilized to exemplify specific embodiments. Directional terms mentioned in the present invention, such as “top” and “down”, “front”, “rear”, “left”, “right”, “inside”, “outside”, “side” and so on are only directions with respect to the attached drawings. Therefore, the used directional terms are utilized to explain and understand the present invention but not to limit the present invention.

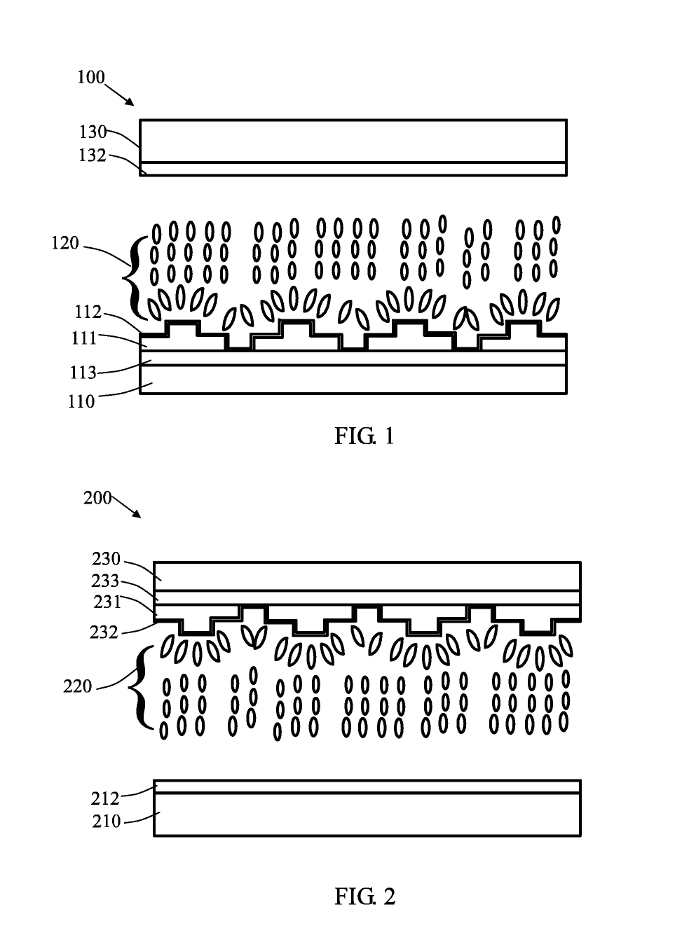

FIG. 1 depicts a schematic drawing illustrating a liquid crystal display device according to a first preferred embodiment of the present invention. The liquid crystal display device 100 includes a first glass substrate 110, a liquid crystal layer 120, and a second glass substrate 130. The liquid crystal layer 120 is disposed between the first glass substrate 110 and the second glass substrate 130, and a plurality of pixel regions is formed on the first glass substrate 110 and the second glass substrate 130. A passive layer 113, a photoresist layer 111 and a transparent electrode layer 112 are sequentially disposed on one side of a first glass substrate 110 adjacent to the liquid crystal layer 120. The photoresist layer 111 forms at least one concave and/or at least one protrusion in each of the pixel regions.

As shown in FIG. 1, the first glass substrate 110 is located below the liquid crystal layer 120. The passive layer 113, the photoresist layer 111, and the transparent electrode layer 112 are formed sequentially from a bottom to top on one side of the first glass substrate 110 adjacent to the liquid crystal layer 120. The second glass substrate 130 is located above the liquid crystal layer 120. A transparent electrode layer 132 is disposed on one side of the second glass substrate 130 adjacent to the liquid crystal layer 120. The photoresist layer 111 forms concave and/or protrusion (the concave herein can be one or a plurality of concaves, the protrusion herein can be one or a plurality of protrusions, or a combination of the concaves and the protrusions, and a number of the concaves and the protrusions can be specifically set as desired, and specific implementation refers to the following specific embodiments) in a same pixel region, so that the transparent electrode layer 112 also has the corresponding concave and/or protrusion. Because the first glass substrate 110 has the concaves and/or the protrusions, the liquid-crystal molecules of the liquid crystal layer 102 in each pixel of the liquid crystal display device 100 are twisted toward different directions when applying voltages, thereby improving a display effect of the liquid crystal display device 100.

The photoresist layer 111 can form the at least one concave and the plurality of protrusions around the concave in each of the pixel regions, or forms the at least one protrusion and the plurality of concaves around the protrusion in each of the pixel regions. Such structures can achieve a better display effect.

Preferably, a sectional width of the concave and/or the protrusion which is formed on the photoresist layer 111 is 0.5 to 20 micrometers, and a sectional depth is 100 to 1000 angstroms, the above conditions enable the liquid-crystal molecules of the liquid crystal layer 120 to achieve an optimal twist effect. A shape of the concave and/or the protrusion is a circle, a trapezoid, a polygon, and so on, and it can be design as desired.

FIG. 2 depicts a schematic drawing illustrating a liquid crystal display device according to a second preferred embodiment of the present invention. The liquid crystal display device 200 includes a first glass substrate 210, a liquid crystal layer 220, and a second glass substrate 230. The liquid crystal layer 220 is disposed between the first glass substrate 210 and the second glass substrate 230, and a plurality of pixel regions is formed on the first glass substrate 210 and the second glass substrate 230. A passive layer 233, a photoresist layer 231 and a transparent electrode layer 232 are sequentially disposed on one side of a second glass substrate 230 adjacent to the liquid crystal layer 220. The photoresist layer 231 forms at least one concave and/or at least one protrusion in each of the pixel regions.

As shown in FIG. 2, the second glass substrate 230 is located above the liquid crystal layer 220. The passive layer 233, the photoresist layer 231, and the transparent electrode layer 232 are formed sequentially from a top to bottom on one side of the second glass substrate 230 adjacent to the liquid crystal layer 220. The first glass substrate 210 is located below the liquid crystal layer 220. A transparent electrode layer 212 is disposed on side which the first glass substrate 210 is adjacent to the liquid crystal layer 220. The photoresist layer 231 forms concave and/or protrusion (the concave herein can be one or a plurality of concaves, the protrusion herein can be one or a plurality of protrusions, or a combination of the concaves and the protrusions, and a number of the concaves and the protrusions can be specifically set as desired, and specific implementation refers to the following specific embodiments) in a same pixel region, so that the transparent electrode layer 232 also has the corresponding concave and/or protrusion. Because the second glass substrate 230 has the concaves and/or the protrusions, the liquid-crystal molecules of the liquid crystal layer 202 in each pixel of the liquid crystal display device 200 are twisted toward different directions when applying voltages, thereby improving a display effect of the liquid crystal display device 200.

The photoresist layer 231 can form the at least one concave and the plurality of protrusions around the concave in each of the pixel regions, or forms the at least one protrusion and the plurality of concaves around the protrusion in each of the pixel regions. Such structures can achieve a better display effect.

Preferably, a sectional width of the concave and/or the protrusion which is formed on the photoresist layer 231 is 0.5 to 20 micrometers, and a sectional depth is 100 to 1000 angstroms, the above conditions enable the liquid-crystal molecules of the liquid crystal layer 220 to achieve an optimal twist effect. A shape of the concave and/or the protrusion is a circle, a trapezoid, a polygon, and so on, and it can be design as desired.

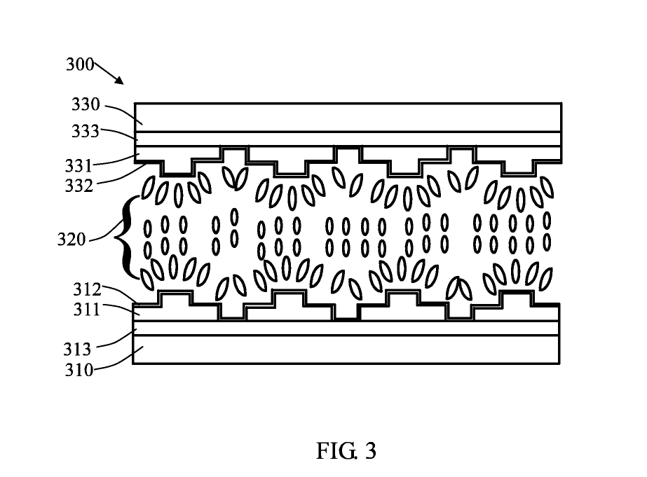

FIG. 3 depicts a schematic drawing illustrating a liquid crystal display device according to a third preferred embodiment of the present invention. The liquid crystal display device 300 includes a first glass substrate 310, a liquid crystal layer 320, and a second glass substrate 330. The liquid crystal layer 320 is disposed between the first glass substrate 310 and the second glass substrate 330, and a plurality of pixel regions is formed on the first glass substrate 310 and the second glass substrate 330. A passive layer 313, a photoresist layer 311 and a transparent electrode layer 312 are sequentially disposed on one side a first glass substrate 310 adjacent to the liquid crystal layer 320. The photoresist layer 311 forms at least one concave and/or at least one protrusion in each of the pixel regions. A passive layer 333, a photoresist layer 331 and a transparent electrode layer 332 are sequentially disposed on one side of a second glass substrate 330 adjacent to the liquid crystal layer 320. The photoresist layer 331 forms at least one concave and/or at least one protrusion in each of the pixel regions.

As shown in FIG. 3, the first glass substrate 310 is located below the liquid crystal layer 320. The passive layer 313, the photoresist layer 311, and the transparent electrode layer 312 are formed sequentially from a bottom to top on one side of the first glass substrate 310 adjacent to the liquid crystal layer 320. The second glass substrate 330 is located above the liquid crystal layer 320. The passive layer 333, the photoresist layer 331, and the transparent electrode layer 332 are formed sequentially from a top to bottom on one side of the second glass substrate 330 adjacent to the liquid crystal layer 320. The photoresist layer 311 and the photoresist layer 331 form concave and/or protrusion (the concave herein can be one or a plurality of concaves, the protrusion herein can be one or a plurality of protrusions, or a combination of the concaves and the protrusions, and a number of the concaves and the protrusions can be specifically set as desired, and specific implementation refers to the following specific embodiments) in a same pixel region, so that the transparent electrode layer 312 and the transparent electrode layer 332 also have the corresponding concave and/or protrusion. Because the first glass substrate 310 and the second glass substrate 330 have the concaves and/or the protrusions, the liquid-crystal molecules of the liquid crystal layer 302 in each pixel of the liquid crystal display device 300 are twisted toward different directions when applying voltages, thereby improving a display effect of the liquid crystal display device 300.

The photoresist layer 311 and the photoresist layer 331 can form the at least one concave and the plurality of protrusions around the concave in each of the pixel regions, or forms the at least one protrusion and the plurality of concaves around the protrusion in each of the pixel regions. Such structures can achieve a better display effect.

In accordance with the liquid crystal display device 300 of the preferred embodiment of the present invention, a shape of photoresist layer 311 on the first glass substrate 310 is different from a shape of photoresist layer 311 on the second glass substrate 330. For example, the photoresist layer 311 on the first glass substrate 310 forms the at least one concave in each of the pixel regions, and the photoresist layer 311 on the second glass substrate 330 forms the at least one protrusion in each of the pixel regions; or the photoresist layer 311 on the first glass substrate 310 forms the at least one protrusion in each of the pixel regions, and the photoresist layer 311 on the second glass substrate 330 forms the at least one concave in each of the pixel regions; or the photoresist layer 311 on the first glass substrate 310 forms the at least one concave and the plurality of protrusions around the concave in each of the pixel regions, and the photoresist layer 311 on the second glass substrate 330 forms the at least one protrusion and the plurality of concaves around the protrusion in each of the pixel regions; or the photoresist layer 311 on the first glass substrate 310 forms the at least one protrusion and the plurality of concaves around the protrusion in each of the pixel regions, and the photoresist layer 311 on the second glass substrate 330 forms the at least one concave and the plurality of protrusions around the concave in each of the pixel regions. Certainly, the configuration with regard to the photoresist layer 311 of the first glass substrate 310 and the corresponding photoresist layer 331 of the second glass substrate 330 is not limited to be implemented in the above-mentioned manners if only the shape of the photoresist layer 311 on the first glass substrate 310 is different from the shape of the photoresist layer 331 on the second glass substrate 330. The concaves and the protrusions can be respectively disposed on the photoresist layers of two different glass substrates such that it is simpler to fabricate the photoresist layer with the whole protrusions or concaves, and the liquid-crystal molecules within the liquid crystal layer 320 have a better twist effect.

Preferably, sectional widths of the concave and/or the protrusion which is formed on the photoresist layer 311 and the photoresist layer 331 are 0.5 to 20 micrometers, and sectional depths are 100 to 1000 angstroms, the above conditions enable the liquid-crystal molecules of the liquid crystal layer 320 to achieve an optimal twist effect. A shape of the concave and/or the protrusion is a circle, a trapezoid, a polygon, and so on, and it can be design as desired.

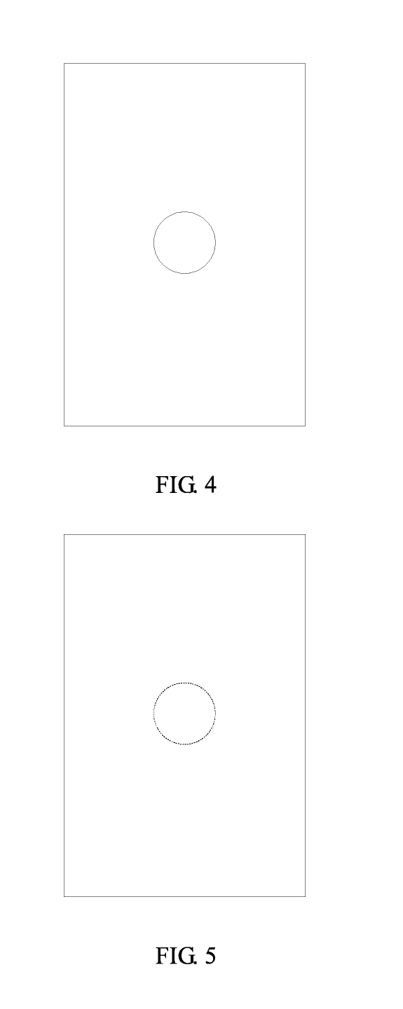

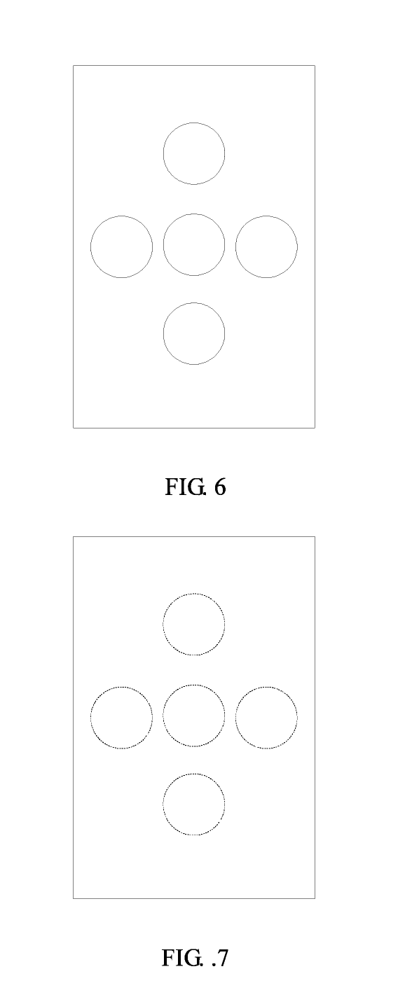

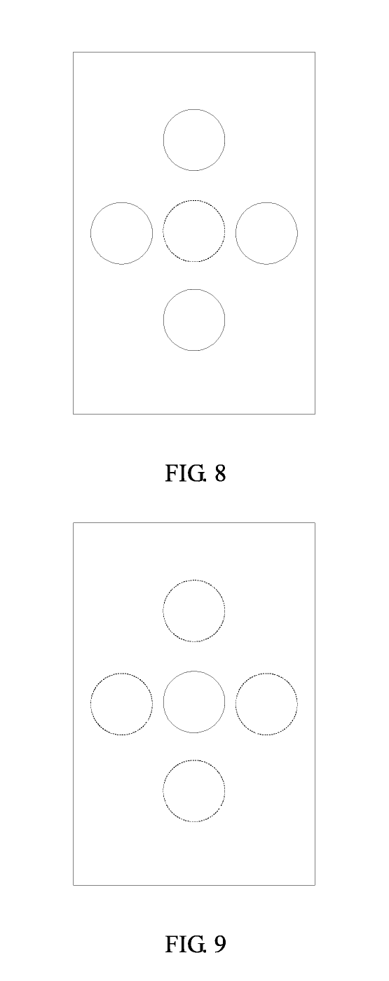

In accordance with the liquid crystal display device of the preferred embodiment of the present invention, the concave and/or the protrusion can be formed on the photoresist layer in a same pixel region. As shown in FIGS. 4-9, in the drawings, the frame indicates the pixel region, and the circle with a solid line indicates the protrusion, and the circle with a dash line indicates the concave. FIG. 4 depicts a protrusion which is formed on the photoresist layer in a same pixel region; FIG. 5 depicts a concave which is formed on the photoresist layer in a same pixel region; FIG. 6 depicts a plurality of protrusions which is formed on the photoresist layer in a same pixel region; FIG. 7 depicts a plurality of concaves which is formed on the photoresist layer in a same pixel region; FIG. 8 depicts a concave and a plurality of protrusions around the concave which are formed on the photoresist layer in a same pixel region; and FIG. 9 depicts a protrusion and a plurality of concaves around the protrusion which are formed on the photoresist layer in a same pixel region. Certainly, a plurality of irregular concaves and protrusions can also be formed simultaneously on the photoresist layer in a same pixel region. The photoresist layer with the concave and/or the protrusion can be disposed on an inside of the first glass substrate or disposed on an inside of the second glass substrate or simultaneously disposed on the insides of the first glass substrate and the second glass substrate; moreover, a number and numerous shapes of the concaves and the protrusions are not limited thereof.

The present invention further relates a method for fabricating a liquid crystal display device, comprising the steps of: (A) sequentially depositing a passive layer and a photoresist layer on a glass substrate; (B) patterning the photoresist layer through a photo mask to form at least one concave and/or at least one protrusion on the photoresist layer; (C) depositing a transparent electrode layer on the photoresist layer.

The fabricating method of the liquid crystal display device of the present invention is to firstly deposit sequentially a passive layer and a photoresist layer on a glass substrate; then secondly patterning the photoresist layer by using the photo mask to form the concave and/or the protrusion on the photoresist layer, numerous lithography processes are employed to form the concave and/or the protrusion in the same pixel region, and a half tone mask or a gray tone mask is also employed to form the concave and/or the protrusion in the same pixel region in a single process; finally, depositing the transparent electrode layer (Indium Tin oxide layer or Indium Zinc Oxide is preferable) on the photoresist layer where the concave and/or the protrusions have been formed thereon, so that the transparent electrode layer also has the same concave and/or protrusions. Because the second glass substrate has the concaves and/or the protrusions, the liquid-crystal molecules of the liquid crystal layer in each pixel of the liquid crystal display device are twisted toward different directions when applying voltages, thereby improving a display effect of the liquid crystal display device.

Preferably, a sectional width of the concave and/or the protrusion on the photoresist layer which is formed by the fabricating method of the liquid crystal display device of the present invention is 0.5 to 20 micrometers, and a sectional depth is 100 to 1000 angstroms, the above conditions enable the liquid-crystal molecules of the liquid crystal layer to achieve an optimal twist effect. The shape of the concave and/or the protrusion is a circle, a trapezoid, a polygon, and so on, and it can be design as desired. Meanwhile, a number of the concaves and/or the protrusions also can be set as desired.

The liquid crystal display device and the method for fabricating the same of the present invention realize the alignment partition of the liquid crystal display device by means of forming the photoresist layer on the passive layer and fabricating the protrusions and the concaves in the photoresist layer, thus the problems of complicatedly fabricating the alignment partition of the liquid crystal display device in the prior art are solved.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A liquid crystal display device, comprising two glass substrates and a liquid crystal layer disposed between the two glass substrates, a plurality of pixel regions formed on the glass substrates, characterized in that: a photoresist layer and a transparent electrode layer are sequentially disposed on a side of the at least one glass substrate adjacent to the liquid crystal layer, the photoresist layer forms at least one concave and/or at least one protrusion in each of the pixel regions; a sectional width of the concave and/or the protrusion is 0.5 to 20 micrometers; a sectional depth of the concave and/or the protrusion is 100 to 1000 angstroms.

2. The liquid crystal display device according to claim 1, characterized in that the photoresist layer forms the at least one concave and the plurality of protrusions around the concave in each of the pixel regions, or the photoresist layer forms the at least one protrusion and the plurality of concaves around the protrusion in each of the pixel regions.

3. The liquid crystal display device according to claim 1, characterized in that the two glass substrates are respectively a first glass substrate and a second glass substrate, a plurality of pixel regions formed on the first glass substrate and the second glass substrate, the photoresist layers formed on both the first glass substrate and the second glass substrate; a shape of photoresist layer on the first glass substrate is different from a shape of photoresist layer on the second glass substrate.

4. The liquid crystal display device according to claim 3, characterized in that the photoresist layer on the first glass substrate forms at least one concave in each of the pixel regions, and the photoresist layer on the second glass substrate forms at least one protrusion in each of the pixel regions.

5. The liquid crystal display device according to claim 3, characterized in that the photoresist layer on the first glass substrate forms at least one protrusion in each of the pixel regions, and the photoresist layer on the second glass substrate forms at least one concave in each of the pixel regions.

6. The liquid crystal display device according to claim 3, characterized in that the photoresist layer on the first glass substrate forms the at least one concave and the plurality of protrusions around the concave in each of the pixel regions, and the photoresist layer on the second glass substrate forms the at least one protrusion and the plurality of concaves around the protrusion in each of the pixel regions.

7. The liquid crystal display device according to claim 3, characterized in that the photoresist layer on the first glass substrate forms the at least one protrusion and the plurality of concaves around the protrusion in each of the pixel regions, and the photoresist layer on the second glass substrate forms the at least one concave and the plurality of protrusions around the concave in each of the pixel regions.

8. A liquid crystal display device, comprising two glass substrates and a liquid crystal layer disposed between the two glass substrates, a plurality of pixel regions formed on the glass substrates, characterized in that: a photoresist layer and a transparent electrode layer are sequentially disposed on a side of the at least one glass substrate adjacent to the liquid crystal layer, the photoresist layer forms at least one concave and/or at least one protrusion in each of the pixel regions.

9. The liquid crystal display device according to claim 8, characterized in that the photoresist layer forms the at least one concave and the plurality of protrusions around the concave in each of the pixel regions.

10. The liquid crystal display device according to claim 8, characterized in that the photoresist layer forms the at least one protrusion and the plurality of concaves around the protrusion in each of the pixel regions.

11. The liquid crystal display device according to claim 8, characterized in that a sectional width of the concave and/or the protrusion is 0.5 to 20 micrometers.

12. The liquid crystal display device according to claim 8, characterized in that a sectional depth of the concave and/or the protrusion is 100 to 1000 angstroms.

13. The liquid crystal display device according to claim 8, characterized in that a sectional shape of the concave and/or the protrusion is a circle, a trapezoid, or a polygon.

14. The liquid crystal display device according to claim 8, characterized in that the two glass substrates are respectively a first glass substrate and a second glass substrate, the plurality of pixel regions formed on the first glass substrate and the second glass substrate, the photoresist layers formed on both the first glass substrate and the second glass substrate.

15. The liquid crystal display device according to claim 14, characterized in that a shape of the photoresist layer on the first glass substrate is different from a shape of the photoresist layer on the second glass substrate.

16. The liquid crystal display device according to claim 15, characterized in that the photoresist layer on the first glass substrate forms the at least one concave in each of the pixel regions, and the photoresist layer on the second glass substrate forms the at least one protrusion in each of the pixel regions.

17. The liquid crystal display device according to claim 15, characterized in that the photoresist layer on the first glass substrate forms the at least one protrusion in each of the pixel regions, and the photoresist layer on the second glass substrate forms the at least one concave in each of the pixel regions.

18. The liquid crystal display device according to claim 15, characterized in that the photoresist layer on the first glass substrate forms at least one concave and the plurality of protrusions around the concave in each of the pixel regions, and the photoresist layer on the second glass substrate forms at least one protrusion and the plurality of concaves around the protrusion in each of the pixel regions.

19. The liquid crystal display device according to claim 15, characterized in that the photoresist layer on the first glass substrate forms at least one protrusion and the plurality of concaves around the protrusion in each of the pixel regions, and the photoresist layer on the second glass substrate forms at least one concave and the plurality of protrusions around the concave in each of the pixel regions.

20. A method for fabricating a liquid crystal display device, characterized in that, comprises the steps of:
(A) sequentially depositing a passive layer and a photoresist layer on a glass substrate;
(B) patterning the photoresist layer through a photo mask for the photoresist layer to form at least one concave and/or at least one protrusion;
(C) depositing a transparent electrode layer on the photoresist layer.
